(19) United States
(12) Patent Application Publication
(10) Pub. No.: US 2025/0294938 A1
(43) Pub. Date: Sep. 18, 2025

(54) METHOD AND APPARATUS FOR ELECTRICAL BOND PROTECTION

(71) Applicant: Lumileds LLC, San Jose, CA (US)

(72) Inventors: Frank Giese, Aachen (DE); Michael Deckers, Jülich (DE); Thorsten Lenzen, Aachen (DE); Marc Droegeler, Aachen (DE); Matthias Holtrup, Aachen (DE); Harry Gijsbers, Heerlen (NL); Joseph Jacobs, Eygelshoven (NL)

(73) Assignee: Lumileds LLC, San Jose, CA (US)

(21) Appl. No.: 18/605,344

(22) Filed: Mar. 14, 2024

(51) Int. Cl. H01L 33/64; H01L 23/00; H01L 33/62

(52) U.S. Cl. CPC H10H 20/8582; H01L 24/48; H01L 24/49; H10H 20/857; H01L 2224/4809; H01L 2224/48091; H01L 2224/48225; H01L 2224/49051; H01L 2224/49052; H10H 20/0364; H10H 20/0365

(57) ABSTRACT

A method for forming a light-emitting device, a non-transitory computer storage medium storing instructions for manufacturing and a light-emitting device that improve the reliability of light-emitting diode (LED) systems. The reliability is improved by: attaching a printed circuit board (PCB) to a heat sink, then attaching a top contact LED to the same heat sink, and electrically connecting the PCB to the LED using conductive elements, such as wires that may be bent upwards or downwards. This comprehensive approach not only ensures efficient heat management and electrical connectivity but also protects and isolates the conductive elements, enhancing the durability and performance of the light-emitting device.

### FIELD OF THE INVENTION

The present invention generally relates to light-emitting diodes (LEDs) and, more particularly, to protecting the wire bonds used to form an electrical connection between a light-emitting diode and another electrical component.

### BACKGROUND OF THE INVENTION

Top-contact LEDs are a type of LED (Light Emitting Diode) design where the electrical contacts, usually in the form of thin metallic layers or pads, are placed on the top surface of the LED body. This contrasts with other designs where one of the contacts might be on the bottom or sides of the semiconductor wafer.

The basic structure of an LED includes a semiconductor material made up of a p-type layer and an n-type layer. When a current flows through the semiconductor, it recombines electrons and holes (absence of electrons) in the junction between the p-type and n-type layers, emitting photons as a result.

In top-contact LEDs, both the anode and the cathode contacts are located on the top surface of the LED body. Special techniques are often employed to ensure that the contacts do not obstruct the light emission pathway. These can include using transparent conductive oxides for the contact layers or designing the contacts as a mesh or grid, thus allowing the light to escape while still providing a sufficient area for electrical contact.

Printed Circuit Boards (PCBs) are fundamental components in modern electronic devices, serving as the backbone for connecting various electronic components in a compact and efficient manner. Essentially, a PCB is a board made of non-conductive material, such as fiberglass or composite epoxy, onto which conductive pathways or traces are etched or printed. These traces replace the bulky wires used in older devices, allowing for much smaller and more reliable connections between components. The PCB supports and electrically connects components like resistors, capacitors, and integrated circuits (ICs) through these conductive pathways, pads, and other features etched from copper sheets laminated onto a non-conductive substrate. Components are usually soldered onto the PCB to both physically secure them and electrically connect them to the board.

Top-contact LEDs offer several advantages that can simplify their implementation and use. Top contact LEDs can be directly attached to a heatsink (e.g., by gluing.) This replaces the solder interface, the PCB, and the Thermal Interface Material (TIM) interface between the PCB and heatsink in the thermal path with respect to classical SMD LEDs. The shorter thermal path may improve thermal performance and reliability.

Designing top-contact LEDs comes with its own set of challenges, including the potential for optical loss due to electrical contacts that may block or absorb the emitted light. Furthermore, making these contacts sufficiently thin to allow light passage can inadvertently increase electrical resistance, thereby reducing the LED's overall efficiency. To mitigate these issues, the geometry of the electrical contacts often needs to be intricately designed, which can add complexity and potentially increase manufacturing costs.

Surface Mount Device (SMD) LEDs are a type of LED component that is mounted directly onto the surface of a Printed Circuit Board (PCB). Unlike traditional through-hole LEDs, which have long leads that go through holes in the PCB and are soldered on the opposite side, SMD LEDs have small metal contacts that can be directly soldered onto pads on the same side of the PCB where the component is located. This makes for a more compact and efficient design, allowing for higher component density and a simpler assembly process.

SMD LEDs are generally more versatile and suitable for a broader range of applications and mass production, thanks to their small size and compatibility with surface-mount technology. Top-contact LEDs, on the other hand, have specialized applications (such as automotive headlights) and are not as commonly found in high-density PCBs or consumer products. Their design focus is more on the arrangement of contacts on the semiconductor material, which can have both advantages and disadvantages in terms of manufacturing complexity, efficiency, and thermal management. For example, top contact LEDs are typically glued to a heat sink, which allows for precise positional placement, whereas SMD LEDs are typically soldered onto a heat sink.

A heat sink is a device designed to absorb and disperse heat away from a high-temperature object, such as a computer processor, a power transistor, or, in this case, an LED. In LED lighting systems, heat sinks play a crucial role in managing the heat generated during the LED's operation. The heat sink conducts heat away from the LED and dissipates it into the surrounding environment, usually through convection.

LEDs are more energy-efficient compared to traditional incandescent and fluorescent lighting technologies, converting a greater percentage of electrical energy into light rather than waste heat. However, they still generate heat during operation. The Excessive heat can (1) Reduce the efficiency of the LED, as the light output can decrease when temperatures rise; (2) Shorten the lifespan of the LED; (3) Affect the color quality of the emitted light; or (4) Lead to potential safety risks in extreme cases, although these are generally well-controlled. Accordingly, the goal of a properly designed heat sink is to manage the heat generated by the LED in order to help maintain the efficiency, longevity, and safety of LED lighting systems.

Passive heat sinks generally consist of fins made of a metal with high thermal conductivity (e.g., aluminum or copper) that transfer heat through natural convection and radiation. In designing a passive heat sink, the surface area is a critical design consideration. A larger surface area allows for more efficient heat dissipation. Therefore, many heat sinks have fins or other intricate shapes to maximize the surface area. In addition, the placement of the heat sink is another critical consideration in the design of a passive heat sink. The heat sink needs to be in close contact with the LED to ensure efficient thermal conductivity. Thermal paste or pads are often used to improve this contact.

Wire ribbons, often referred to as ribbon cables or flat ribbon cables, are a type of electrical cable that consists of multiple conducting wires running parallel to each other on the same flat plane. The individual wires within the ribbon are typically insulated from each other, and the uniform arrangement allows for a compact, organized, and flexible solution for connecting electronic components. Ribbon cables are particularly valued for their ability to simplify connections between components or boards within electronic systems, reducing the space and weight compared to traditional wire bundles.

Industrial robots in electronic manufacturing have become pivotal in enhancing efficiency, precision, and reliability across the production process. These sophisticated machines are designed to perform a wide range of tasks, including assembling circuit boards, soldering and welding components, handling delicate parts, and conducting inspections with high accuracy. Equipped with advanced vision systems and precise motion control, industrial robots can quickly adapt to various tasks, ensuring consistent product quality even in the most intricate electronic assembly operations. Their ability to work tirelessly around the clock, combined with the precision and repeatability far surpassing human capabilities, significantly reduces production times and costs, while minimizing errors and waste.

### SUMMARY OF THE INVENTION

Automobile headlight modules may also include a circuit board that is electrically connected to one or more LEDs to control power delivery to the LEDs. Standard wire connectors, such as ribbon bonds, are typically used to form the electrical connection due to their low cost and ease of attachment; however, these wires are thin and may easily deform if contacted during headlight module assembly. This deformation may put the wires in contact with a heat sink or other conductive element and thereby create an electrical short. Further, deformed wires may exhibit reliability issues. Disclosed embodiments overcome at least these limitations of conventional systems.

### BRIEF DESCRIPTION OF THE DRAWINGS

Features and advantages of the method disclosed and taught herein will be apparent from the detailed description which follows, taken in conjunction with the accompanying drawings, which together illustrate, by way of example, features of the disclosed embodiments, and in which:

FIG. 1 is a schematic view of a device in accordance with one or more embodiments of the present disclosure.

FIG. 2 is a schematic view of a device in accordance with one or more embodiments of the present disclosure.

FIG. 3 is a schematic view of a device in accordance with one or more embodiments of the present disclosure.

FIG. 4A illustrates a wire in accordance with one or more embodiments of the present disclosure.

FIG. 4B illustrates a wire in accordance with one or more embodiments of the present disclosure.

FIG. 4C illustrates a wire in accordance with one or more embodiments of the present disclosure.

FIG. 5 is a schematic view of a device in accordance with one or more embodiments of the present disclosure.

FIG. 6 is a schematic view of a device in accordance with one or more embodiments of the present disclosure.

FIG. 7A is a schematic view of a device in accordance with one or more embodiments of the present disclosure.

FIG. 7B is a schematic view of a device in accordance with one or more embodiments of the present disclosure.

FIG. 8A is a schematic view of a device in accordance with one or more embodiments of the present disclosure.

FIG. 8B is a schematic view of a device in accordance with one or more embodiments of the present disclosure.

FIG. 8C is a schematic view of a device in accordance with one or more embodiments of the present disclosure.

FIG. 8D is a schematic view of a device in accordance with one or more embodiments of the present disclosure.

FIG. 9 is a top view of the electronics board which incorporates an LED according to an embodiment.

FIG. 10 is a diagram of an example application system.

FIG. 11 is a flow diagram for an example process to produce devices in accordance with embodiments.

### DETAILED DESCRIPTION OF THE PREFERRED EMBODIMENTS

Examples of different light illumination systems and/or light-emitting diode implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only, and they are not intended to limit the disclosure in any way. Like numbers refer to like elements throughout.

It will be understood that, although the terms first, second, third, etc., may be used herein to describe various elements, these elements should not be limited by these terms. These terms may be used to distinguish one element from another. For example, a first element may be termed a second element, and a second element may be termed a first element without departing from the scope of the present invention. As used herein, the term “and/or” may include any and all combinations of one or more of the items listed in the associated list.

It will be understood that when an element such as a layer, region, or substrate is referred to as being “on” or extending “onto” another element, it may be directly on or extend directly onto the other element, or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,” “lower,” “horizontal,” or “vertical” may be used herein to describe a relationship of one element, layer, or region to another element, layer, or region as illustrated in the figures. It will be understood that these terms are intended to encompass different orientations of the device in addition to the orientation depicted in the figures.

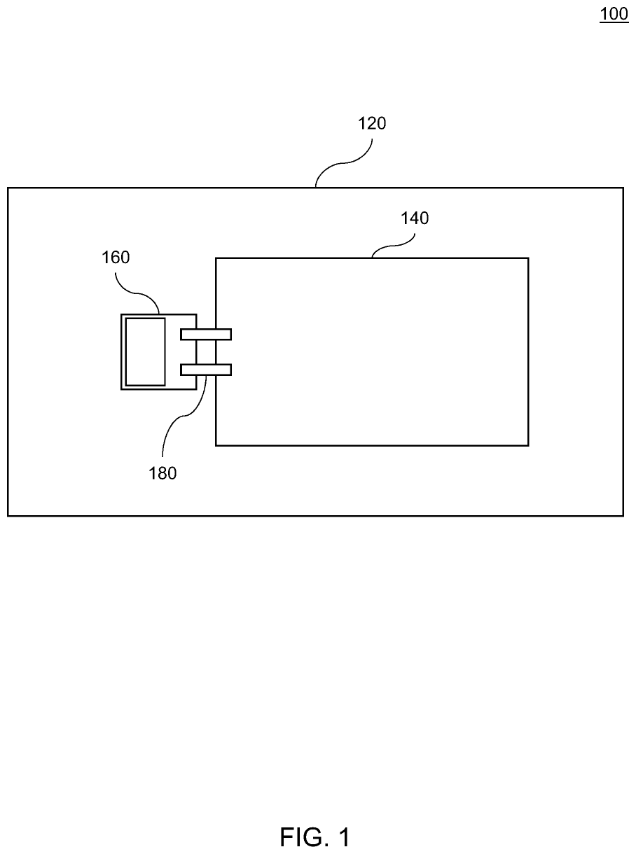

FIG. 1 illustrates an example device 100 embodying the teachings herein. The device comprises a heat sink 120, a circuit board 140, a top contact LED 160, and one or more wires 180, which form an electrical connection between the circuit board and the LED.

The heat sink 120 may be an integrated heat sink that forms the main body of the device. The heat sink 120 may be constructed from a material with a high thermal conductivity to facilitate the quick absorption of heat produced by the other device elements. In some instances, the heat sink may be formed of a metal such as a metal (e.g., aluminum or copper) or the alloys of the metal. In some cases, the heat sink may include a phase change material.

The circuit board 140 may be connected to the heat sink via screws or other fasteners. In some instances, the heat sink 120 may be glued using a thermally conductive adhesive. In other instances, the heat sink 120 may be welded to the circuit board 140. The circuit board 140 comprises all necessary electrical components for controlling the functioning of the device apart from the top contact LED 160. In other instances, the heat sink may be riveted.

The top contact LED 160 may be fixed to the heat sink 120 via a glue, such as silver-filled silicone glue. The top contact LED 160 includes an anode and a cathode, both of which are accessible from the top of the LED. Electrical bonds to the anode and cathode are typically made via a bonding process, such as ultrasonic welding.

The one or more wires 180 may be ribbons or another type of wire. The one or more wires 180 may be connected to the circuit board 140 and the top contact LED 160 via a bonding process, such as ultrasonic welding.

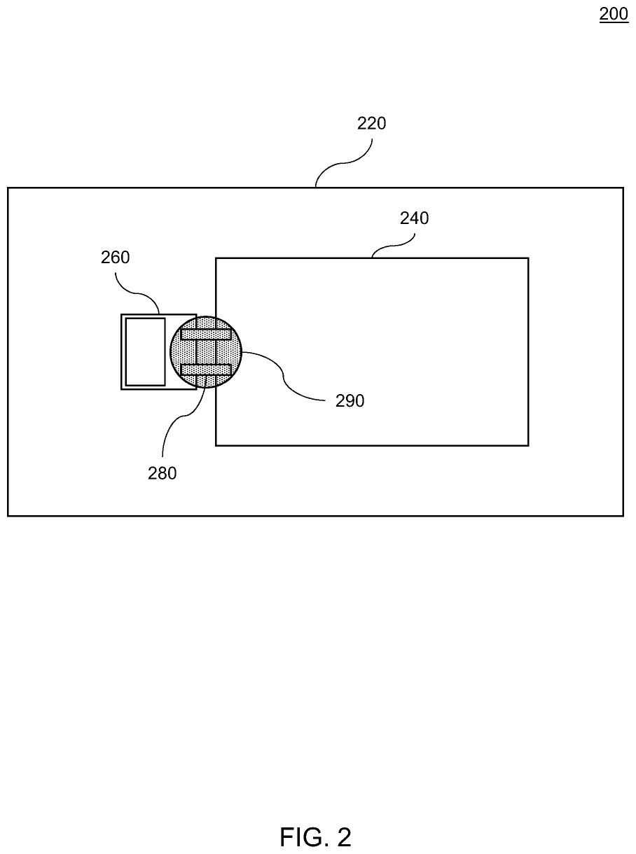

FIG. 2 illustrates an embodiment of the device 200 in which an adhesive glob top 290 is used to protect one or more wires 280. The glob top 290 covers at least a portion of the one or more wires 280 to prevent them from deforming or contacting heat sink 220 below. The glob top may further cover the bonding points between the one or more wires 280 and the circuit board 240 or top contact LED 260. In some instances, the glob top 290 is formed from epoxy or silicone.

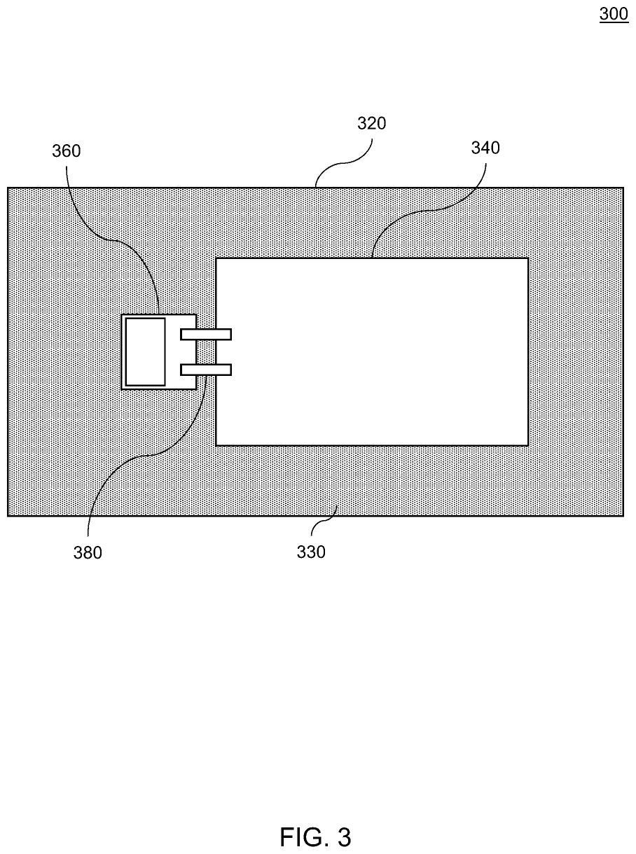

FIG. 3 illustrates an embodiment of the device 300 in which a conformal coating 330 is used to protect one or wires 380 against an electrical short. The conformal coating 330 is applied to heat sink 320 to electrically isolate it. In the event that the one or more wires 380 become deformed and come into contact the conformal coating 330, the conformal coating 330 blocks an electrical short from occurring between the one or more wires 380 and the heat sink 320. In some instances, the conformal coating 330 is formed from epoxy or silicone.

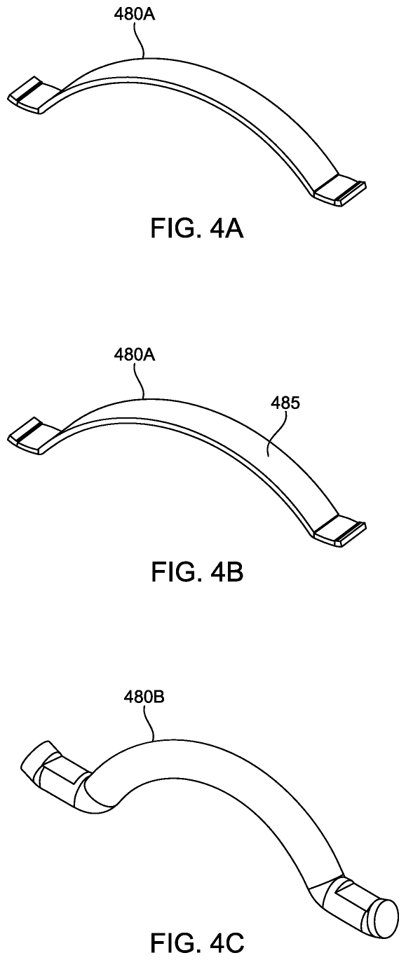

FIG. 4A illustrates a type of wire 480A that may be used in the device embodiments discussed herein. The wire 480A is a metal ribbon bond capable of safely supporting an electrical current of 2 A or greater. The ribbon 480A has a preferred thickness in the range of 300-400 μm. The ends of the wire 480A may be fixed to a circuit board and a top contact LED via a bonding process, such as ultrasonic welding. The wire 480A has a curvature to reduce the mechanical stress on the bonds with a circuit board and a top contact LED. Further, the curvature enables the wire 480A to flex in response to thermal expansion or contraction. This improves its robustness against breaking or otherwise deteriorating.

FIG. 4B illustrates an alternative to the wire 480A, which may be used in the device embodiments discussed herein. The wire 480A is coated with a conformal coating 485 to electrically isolate the wire 480A and hence protect it against an electrical short with other conductive elements in the vicinity thereof, such as a heat sink. In the event that one or more wires 480A coated with conformal coating 485 are incorporated in a device as discussed herein and become deformed, the conformal coating 485 blocks an electrical short from occurring between the one or more wires 480A and other conductive elements in the vicinity thereof.

FIG. 4C illustrates a type of wire 480B that may be used in the device embodiments discussed herein. The wire 480B is a metal wire which is thicker than a ribbon bond. The increased thickness of the wire 480B relative to a wire of the ribbon bond variety improves the stability of the wire and decreases the ease at which it may become deformed. The ends of the wire 480B may be fixed to a top contact LED and a circuit board via a bonding process, such as ultrasonic welding. The conformal coating 485 discussed above may be coated onto the wire 480B via a similar process to electrically isolate the wire 480B and hence protect it against an electrical short with other conductive elements in the vicinity thereof, such as a heat sink.

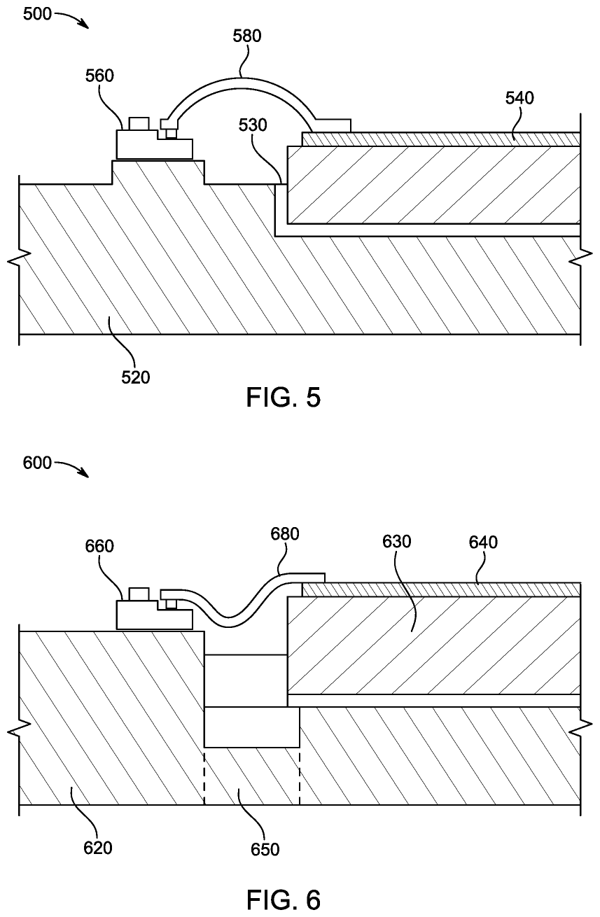

FIG. 5 illustrates an embodiment of the device 500 in which one or more upward-bent wires 580 are utilized. The upward-bent wires 580 forms an electrical bond between a circuit board 540 and a top contact LED 560. The circuit board 540 may be fixed, via screws or otherwise, in a depression in the heat sink 530 of variable depth to control the relative height between the top surface of the circuit board 540 and the top surface of the top contact LED 560.

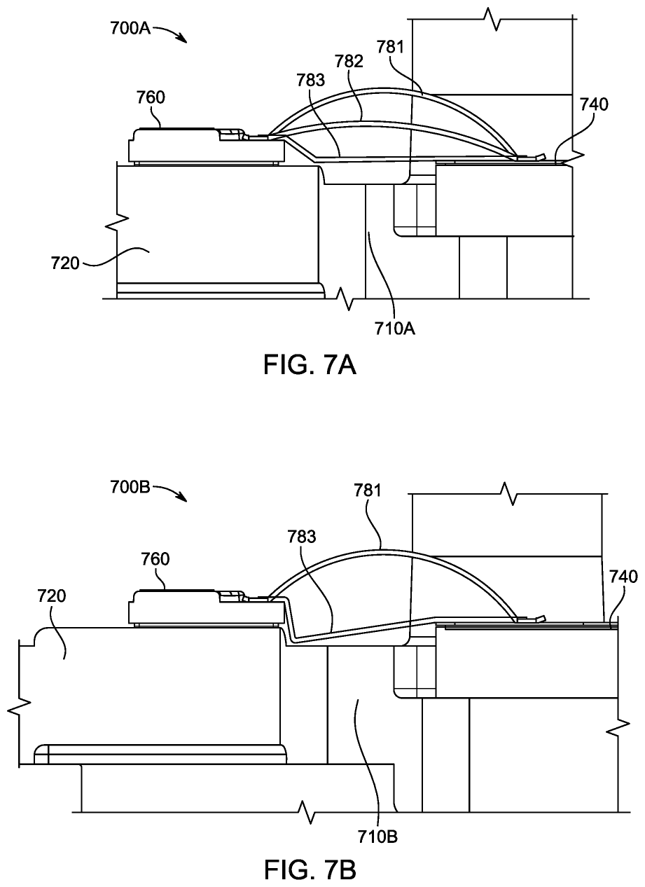

FIG. 6 illustrates an embodiment of the device 600 in which one or more downward-bent wires 680 are utilized. The downward-bent wires 680 may offer an advantage over upward-bent wires 580 in that they do not deform when pressed or otherwise contacted to the same extent as upward-bent wires 580. Otherwise, the downward-bent wires 680 may be constructed and bonded in the same manner as upward-bent wires 580. In some instances, the length of the downward-bent wires 680 is determined so that downward-bent wires 680 are unable to contact the heat sink 620.

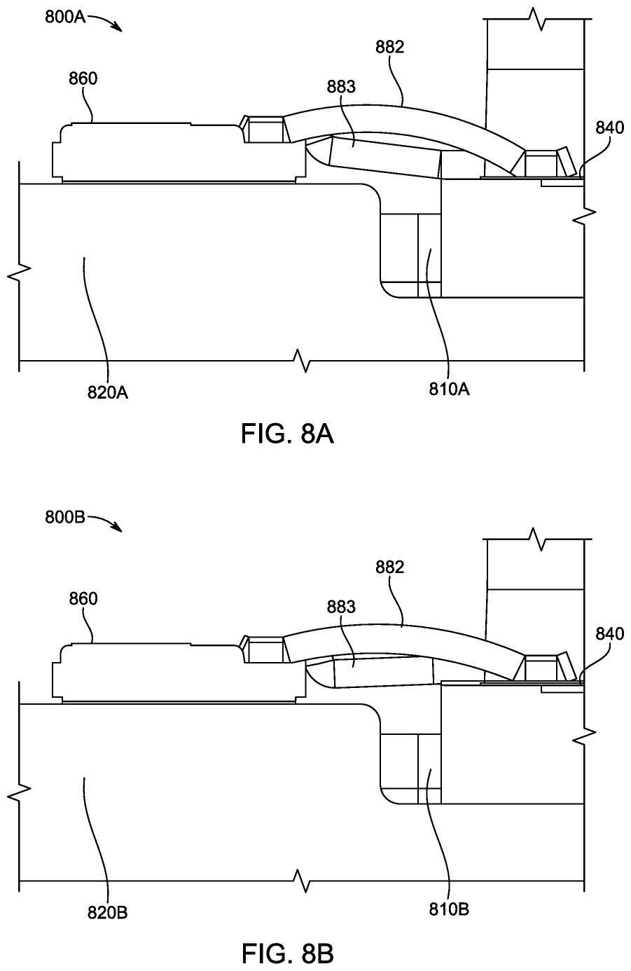

FIG. 7A illustrates an embodiment of the device 700A in which a hole 710A is machined in a heat sink 720 between a circuit board 740 and a top contact LED 760. The hole is proportioned such that one or more wires 782 cannot deform to the point that they contact heat sink 720 or any other conductive elements in the vicinity thereof, provided that the bonds to the circuit board 740 and the top contact LED 760 remain fixed. Each wire 782 must not be too long (or, equivalently, must not have too much curvature) such that there is sufficient slack for a wire 782 to deform and contact heat sink 720 or any other conductive elements in the vicinity thereof. For example, one or more wires 781 are too long and could be deformed such that they contact the heat sink 720 below top contact LED 760, potentially causing an electrical short. Conversely, the wires 782 are just short enough such that, when maximally deformed to shape 783, contact is avoided, and there is no potential for an electrical short.

FIG. 7B illustrates an embodiment of the device 700B in which a hole 710B is machined in a heat sink 720 between a circuit board 740 and a top contact LED 760. The hole 710B is wide such that the edge of the hole is flush with the side of the top contact LED 760. This width enables one or more longer wires 781 to be utilized in the device, which, when maximally deformed to shape 783, avoid contact with heat sink 720 or any other conductive elements in the vicinity thereof. However, when the horizontal distance between the circuit board 740 and top contact LED 760 is too large, the quality of the light produced by the top contact LED 760 may be reduced. Thus, a tradeoff exists between the separation of circuit board 740 and top contact LED 760 and the optical quality of the device 700B.

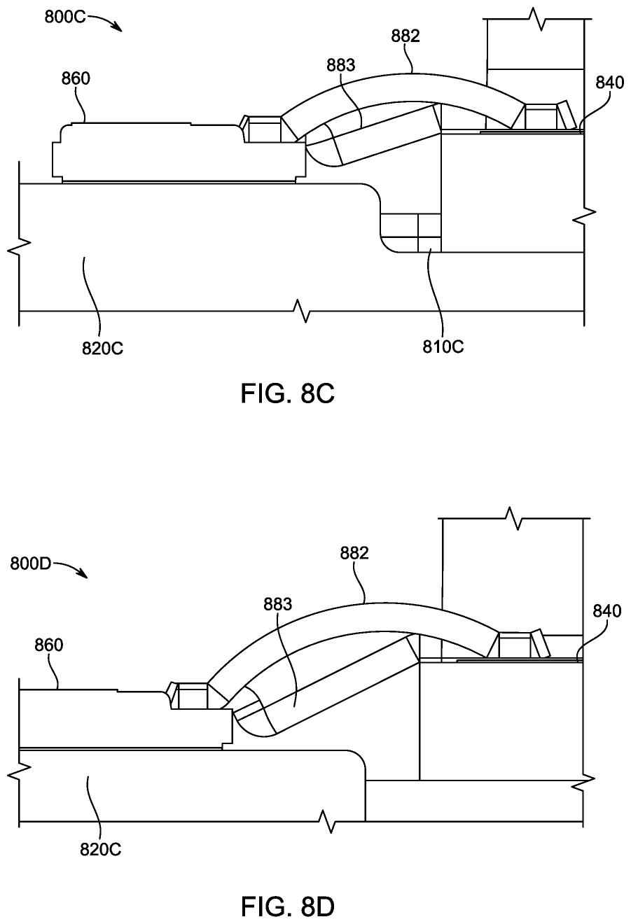

FIG. 8A illustrates an embodiment of the device 800A in which a top surface of a heat sink 820A below a top contact LED 860 is flush with a top surface of a circuit board 840. A hole 810A is machined below one or more wires 882 so that, when maximally deformed to shape 883, the wires 882 avoid contact with heat sink 820A or any other conductive elements in the vicinity thereof. In many instances, the recess and loop shape combination prevents electrical contact between the wire 882 and the heat sink 820a.

FIG. 8B illustrates an embodiment of the device 800B in which a top surface of a circuit board 840 has an intermediate vertical position between a top surface of a heat sink 820B and a top surface of a top contact LED 860. A hole 810B is machined below one or more wires 882 so that, when maximally deformed to shape 883, the wires 882 avoid contact with heat sink 820B or any other conductive elements in the vicinity thereof. The hole 810B may be of a shallower depth than the hole 810A while still ensuring no contact occurs between the wires 882 and any nearby conductive elements.

FIG. 8C illustrates an embodiment of the device 800C in which a top surface of a circuit board 840 is flush with a top surface of a top contact LED 860. A hole 810C is machined below one or more wires 882 so that, when maximally deformed to shape 883, the wires 882 avoid contact with heat sink 820C or any other conductive elements in the vicinity thereof. The hole 810C may be of a shallower depth than any of holes 810A-B while still ensuring no contact occurs between the wires 882 and any nearby conductive elements.

FIG. 8D illustrates an embodiment of the device 800D in which a top surface of a circuit board 840 has a vertical position above a top surface of a top contact LED 860. A hole 810D is machined below one or more wires 882 so that, when maximally deformed to shape 883, the wires 882 avoid contact with heat sink 820D or any other conductive elements in the vicinity thereof. The hole 810D may be of a shallower depth than any of holes 810A-C while still ensuring no contact occurs between the wires 882 and any nearby conductive elements. In some instances, an additional insulating material may be added to the hole 810 to further protect against shorting.

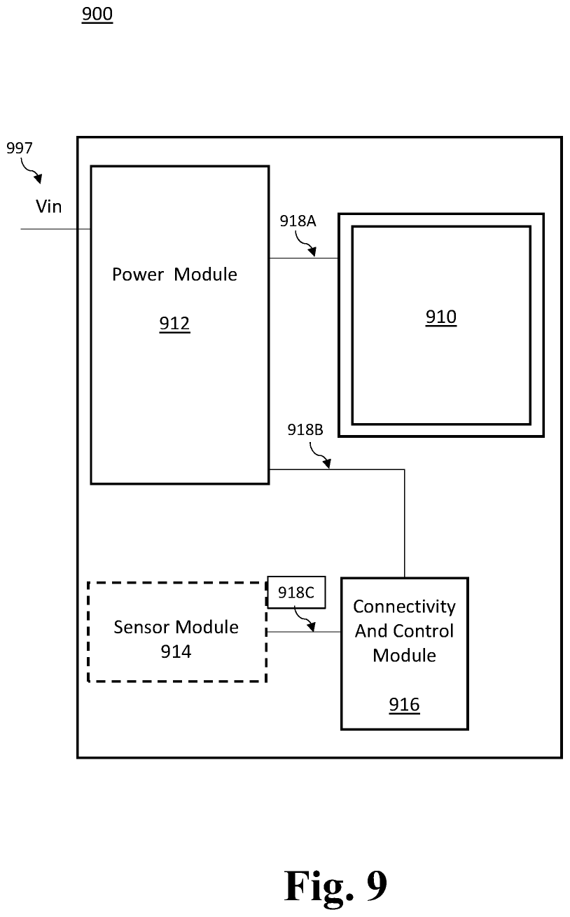

FIG. 9 is a top view of the LED system 900 with an LED 910 attached to the substrate 920. The power module 912 receives a voltage input at Vin 997 and control signals from the connectivity and control module 916 over traces 918B, and provides drive signals to the LED 910 over traces 918A. Traces 918A may implement any of the wire protection techniques illustrated in FIGS. 1-8D.

The LED 910 is turned on and off via the drive signals from the power module 912. In the embodiment shown in FIG. 9, the connectivity and control module 916 receives sensor signals from the sensor module 914 over trace 918C. In some instances, the power module 912, the connect the connectivity and control module 916 and/or the sensor module 914 are incorporated circuit board the circuit board 140, the circuit board 240, the circuit board 340, the circuit board 540, the circuit board 640, the circuit board 740 or the circuit board 840.

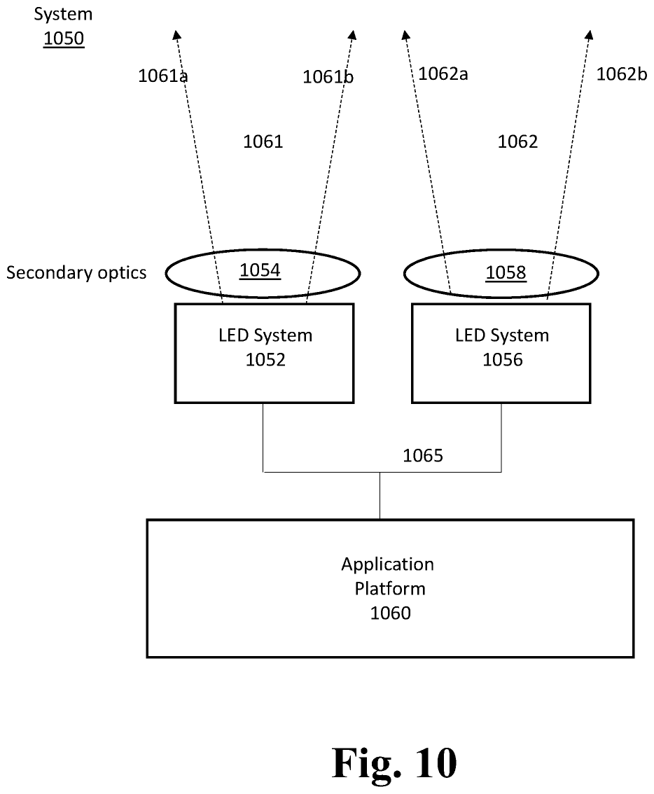

FIG. 10 shows an example system 1050, which includes an application platform 1060, LED systems 1052 and 556, and secondary optics 1054 and 1058. The LED System 1052 produces light beams 1061, shown between arrows 1061a and 1061b. The LED System 1056 may produce light beams 1062 between arrows 1062a and 1062b. In the embodiment shown in FIG. 10, the light emitted from LED system 1052 passes through secondary optics 1054, and the light emitted from the LED System 1056 passes through secondary optics 558. In alternative embodiments, the light beams 1061 and 1062 do not pass through any secondary optics. The secondary optics may be or may include one or more light guides. The one or more light guides may be edge lit or may have an interior opening that defines an interior edge of the light guide. LED systems 1052 and/or 1056 may be inserted in the interior openings of the one or more light guides such that they inject light into the interior edge (interior opening light guide) or exterior edge (edge lit light guide) of the one or more light guides. LEDs in LED systems 1052 and/or 1056 may be arranged around the circumference of a base that is part of the light guide. According to an implementation, the base may be thermally conductive. According to an implementation, the base may be coupled to a heat-dissipating element that is disposed over the light guide. The heat-dissipating element may be arranged to receive heat generated by the LEDs via the thermally conductive base and dissipate the received heat. The one or more light guides may allow light emitted by LED systems 1052 and 1056 to be shaped in a desired manner such as, for example, with a gradient, a chamfered distribution, a narrow distribution, a wide distribution, an angular distribution, or the like.

In example embodiments, the system 1050 may be incorporated in a camera flash system, indoor residential or commercial lighting, outdoor light such as street lighting, an automobile, a medical device, AR/VR devices, and robotic devices. The LED System 900 shown in FIG. 9 is an example embodiment.

In example embodiments, the system 1050 may be a mobile phone of a camera flash system, indoor residential or commercial lighting, outdoor light such as street lighting, an automobile, a medical device, AR/VR devices, and robotic devices. The LED System 900 shown in FIG. 9 is an example embodiment.

The application platform 1060 may provide power to the LED systems 1052 and/or 1056 via a power bus via line 1065 or other applicable input, as discussed herein. Further, application platform 1060 may provide input signals via line 1065 for the operation of the LED system 1052 and LED system 1056, which input may be based on a user input/preference, a sensed reading, a pre-programmed or autonomously determined output, or the like. One or more sensors may be internal or external to the housing of the application platform 1060.

In various embodiments, application platform 1060 sensors and/or LED system 1052 and/or 1056 sensors may collect data such as visual data (e.g., LIDAR data, IR data, data collected via a camera, etc.), audio data, distance based data, movement data, environmental data, or the like or a combination thereof. The data may be related a physical item or entity such as an object, an individual, a vehicle, etc. For example, sensing equipment may collect object proximity data for an ADAS/AV based application, which may prioritize the detection and subsequent action based on the detection of a physical item or entity. The data may be collected based on emitting an optical signal by, for example, LED system 1052 and/or 1056, such as an IR signal and collecting data based on the emitted optical signal. The data may be collected by a different component than the component that emits the optical signal for the data collection. Continuing the example, sensing equipment may be located on an automobile and may emit a beam using a vertical-cavity surface-emitting laser (VCSEL). The one or more sensors may sense a response to the emitted beam or any other applicable input.

In example embodiment, application platform 1060 may represent an automobile, and LED system 1052 and LED system 1056 may represent automobile headlights. In various embodiments, the system 1050 may represent an automobile with steerable light beams where LEDs may be selectively activated to provide steerable light. For example, an array of LEDs may be used to define or project a shape or pattern or illuminate only selected sections of a roadway. In an example embodiment, Infrared cameras or detector pixels within LED systems 1052 and/or 1056 may be sensors that identify portions of a scene (roadway, pedestrian crossing, etc.) that require illumination.

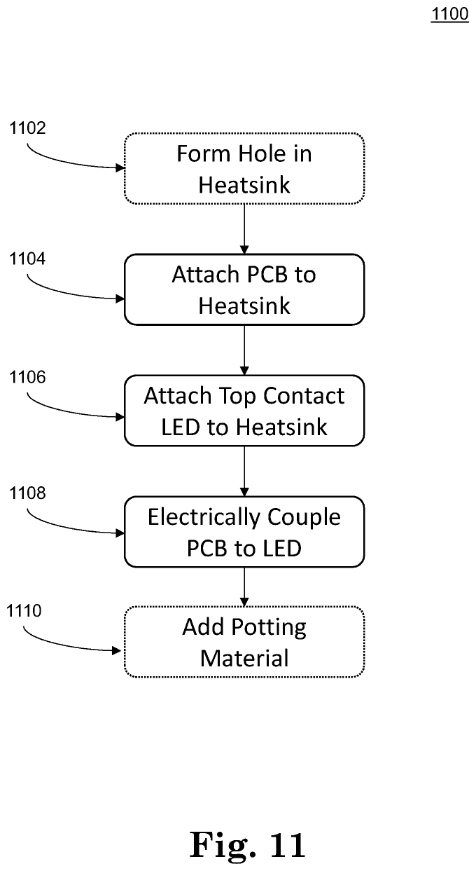

FIG. 11 illustrates an method 1100 that can be implemented to produce the devices according to embodiments. Optionally, in step 1102 a hole (e.g., hole 710A, 710B, or 810A-D), is formed in a heat sink (e.g., heat sink 120, 220, 320, 420, 520, 620, 720, or 820). In some instances, the hole is formed by milling, drilling, and/or punching. In other instances, the hole is formed by casting or forming the heat sink. In some instances, the hole may include an insulating material that further protects the wires against shorting.

In step 1104, the Printed Circuit Board (PCB) (e.g., circuit board 140, 240, 340, 440, 540, 640, 740, or 840) is attached to the heat sink. In some instances, the PCB is attached to the heat sink using fasteners. In other instances, conductive adhesives are used. In yet other instances, the PCB is connected to the heat sink via a bonding process, such as riveting.

Then, in step 1106, the top contact LED (e.g., LED 160, 260, 360, 560, 660, 760, or 860) is attached to the heat sink. In some instances, the top contact LED is attached to the heat sink using fasteners. In other instances, conductive adhesives are used. In yet other instances, the top contact LED is connected to the heat sink via a bonding process, such as soldering.

In step 1108, the top contact LED is electrically coupled to the PCB. In some instances, the top contact LED is electrically coupled to the PCB using a wire or ribbon such as wire 480A or wire 480B. In other instances, the top contact LED is electrically coupled to the PCB using wires 781, 782, and/or 783. In further instances, the top contact LED is electrically coupled to the PCB using wires such as wire 882 or downward bent-wires 680.

Optionally, in step 1110, the wires electrically coupling the top contact LED to the PCB are coated with a non-conductive material (e.g., glob top 290).

In some instances, the method 1100 may be performed by one or more industrial robots. In such cases, the one or more industrial robots execute instructions stored on one or more non-transitory computer-readable medium, and the instructions cause the one or more industrial robots to perform method 1000. A non-transitory computer-readable medium refers to a type of physical storage that holds data or instructions in a format readable by a computer or other digital devices, in a manner that is persistent and not fleeting like electrical signals or transmissions. Unlike volatile memory, which requires power to maintain the information stored within it, non-transitory media retain information without the need for a constant power supply, allowing for long-term storage and retrieval. This category encompasses a wide array of storage solutions, including hard drives, solid-state drives (SSDs), optical discs (such as CDs, DVDs), USB flash drives, and memory cards. These media are crucial for the distribution of software, storage of user data, archiving, and as a means for devices to boot and operate.

The instructions stored on the non-transitory computer-readable medium may be written in any of the proprietary languages developed by robot manufacturers or high-level general programming languages. Examples of proprietary languages include ABB's RAPID, KUKA's KRL (KUKA Robot Language), and Fanuc's TP (Teach Pendant) language, are designed to make the most of their robots' features, allowing for direct control over movements, speed, and precision tasks. However, high level general programming languages like Python, C++, and Java may be used for their flexibility, extensive libraries, and community support. Python, for instance, is popular for its simplicity and readability, along with powerful libraries like ROS (Robot Operating System).

Having described the embodiments in detail, those skilled in the art will appreciate that, given the present description, modifications may be made to the embodiments described herein without departing from the spirit of the disclosure. Therefore, it is not intended that the scope of the disclosure be limited to the specific embodiments illustrated and described.

What is claimed is:

1. A method for forming a light emitting device, the method comprising:
attaching a printed circuit board to a heat sink;
attaching a top contact light emitting diode (LED) to the heat sink; and
electrically coupling the printed circuit board to the top contact LED via conductive elements.

2. The method of claim 1, further comprising:
encapsulating the conductive elements by applying an adhesive glob top.

3. The method of claim 1, further comprising:
applying a conformal coating to the conductive elements, wherein the conformal coating isolates the conductive elements.

4. The method of claim 1, wherein the conductive elements include one or more downward-bent wires.

5. The method of claim 1, wherein the conductive elements include one or more upward-bent wires.

6. The method of claim 1, further comprising:
forming a hole in the heat sink, wherein the printed circuit board and the top contact LED are located on opposite sides of the hole and the conductive elements span the hole.

7. The method of claim 1, wherein the top contact LED is attached to the heat sink at a point that is higher than a location where the printed circuit board is attached

8. A non-transitory computer readable storage medium storing instructions that when executed by one or more industrial robots, cause the one or more industrial robots to collectively execute a method comprising:
attaching a printed circuit board to a heat sink;
attaching a top contact light emitting diode (LED) to the heat sink; and
electrically coupling the printed circuit board to the top contact LED via conductive elements.

9. The non-transitory computer readable storage medium of claim 8, wherein the method further comprises:
encapsulating the conductive elements by applying an adhesive glob top.

10. The non-transitory computer readable storage medium of claim 8, wherein the method further comprises:
applying a conformal coating to the conductive elements, wherein the conformal coating isolates the conductive elements.

11. The non-transitory computer readable storage medium of claim 8, wherein the conductive elements include one or more downward-bent wires.

12. The non-transitory computer readable storage medium of claim 8, wherein the conductive elements include one or more upward-bent wires.

13. The non-transitory computer readable storage medium of claim 8, wherein the method further comprises:
forming a hole in the heat sink, wherein the printed circuit board and the top contact LED are located on opposite sides of the hole and the conductive elements span the hole.

14. The non-transitory computer readable storage medium of claim 8, wherein the top contact LED is attached to the heat sink at a point that is higher than a location where the printed circuit board is attached.

15. A light emitting device manufactured by a method, the method comprising:
attaching a printed circuit board to a heat sink;
attaching a top contact light emitting diode (LED) to the heat sink; and
electrically coupling the printed circuit board to the top contact LED via conductive elements.

16. The light emitting device of claim 15, wherein the method further comprises:
encapsulating the conductive elements by applying an adhesive glob top.

17. The light emitting device of claim 15, wherein the method further comprises:
applying a conformal coating to the conductive elements, wherein the conformal coating isolates the conductive elements.

18. The light emitting device of claim 15, wherein the conductive elements include one or more downward-bent wires or one or more upward-bent wires.

19. The light emitting device of claim 15, wherein the method further comprises:
forming a hole in the heat sink, wherein the printed circuit board and the top contact LED are located on opposite sides of the hole and the conductive elements span the hole.

20. The light emitting device of claim 15, wherein the top contact LED is attached to the heat sink at a point that is higher than a location where the printed circuit board is attached.
